(19) United States
(12) Patent Application Publication
(10) Pub. No.: US 2025/0017051 A1
(43) Pub. Date: Jan. 9, 2025

(54) DISPLAY DEVICE AND ELECTRONIC DEVICE

(71) Applicant: SONY SEMICONDUCTOR SOLUTIONS CORPORATION, KANAGAWA (JP)

(72) Inventors: KENICHI AOYAGI, KANAGAWA (JP); DAICHI IMABAYASHI, KANAGAWA (JP); TATSUYA KANO, KANAGAWA (JP); TOMOYOSHI ICHIKAWA, KANAGAWA (JP)

(21) Appl. No.: 18/711,150

(22) PCT Filed: Nov. 14, 2022
(86) PCT No.: PCT/JP2022/042251

§ 371 Date: May 17, 2024

(30) Foreign Application Priority Data
Nov. 26, 2021 (JP) 2021-192338

(51) Int. Cl. H10K 59/122; H10K 59/35; H10K 59/80

(52) U.S. Cl. CPC H10K 59/122; H10K 59/80521; H10K 59/35

(57) ABSTRACT

Provided is a display device capable of preventing a common electrode from coming into contact with a lateral surface of an organic layer. The display device includes a plurality of light emitting elements, an insulating member, and a common electrode. The plurality of light emitting elements is two-dimensionally arranged. The light emitting elements each include a first electrode, an organic layer including a light emitting layer, and a second electrode in this order. The first electrode, the organic layer, and the second electrode are isolated for each of the light emitting elements. The common electrode is provided on the second electrodes of two or more of the light emitting elements. The insulating member covers the lateral surface of the organic layer of each of the light emitting elements.

### TECHNICAL FIELD

The present disclosure relates to a display device and an electronic device including the display device.

### BACKGROUND ART

Organic light emitting diode (OLED) display devices have been widely used recently. Such an OLED display device includes a plurality of light emitting elements two-dimensionally arranged on a circuit board, and each light emitting element includes a first electrode, an organic layer including a light emitting layer, and a second electrode in this order.

In order to improve the characteristics of the OLED display device, various studies have been made on the configuration of the light emitting element. Patent Document 1 discloses a light emitting element including a lower electrode, an organic compound layer, and an upper electrode, and the upper electrode includes a first upper electrode layer and a second upper electrode layer (common electrode). Furthermore, Patent Document 1 discloses that a configuration where a film end of the organic compound layer is covered with the upper electrode, more specifically, the first upper electrode layer and the second upper electrode layer constituting the upper electrode prevents degradation of the organic compound layer.

### CITATION LIST

### Patent Document

Patent Document 1: Japanese Patent Application Laid-Open No. 2016-21380

### SUMMARY OF THE INVENTION

### Problems to be Solved by the Invention

In the display device disclosed in Patent Document 1, the second upper electrode layer (common electrode), however, is in contact with a lateral surface of the organic compound layer (organic layer including the light emitting layer), so that there is a possibility that the lower electrode and the second upper electrode layer are short-circuited. Furthermore, when the second upper electrode layer comes into contact with the lateral surface of the organic compound layer, there is also a possibility that abnormal light emission occurs on the lateral surface of the organic compound layer. In particular, in a case where the organic compound layer includes a highly conductive material or a highly conductive layer, a short circuit between the lower electrode and the second upper electrode layer or abnormal light emission on the lateral surface of the organic compound layer occurs easily.

It is therefore an object of the present disclosure to provide a display device capable of preventing a common electrode from coming into contact with a lateral surface of an organic layer, and an electronic device including the display device.

### Solutions to Problems

In order to solve the above-described problems, a display device according to the present disclosure includes:
a plurality of light emitting elements;
an insulating member; and
a common electrode, in which
the plurality of light emitting elements is two-dimensionally arranged,
the light emitting elements each include a first electrode, an organic layer including a light emitting layer, and a second electrode in this order,
the first electrode, the organic layer, and the second electrode are isolated for each of the light emitting elements,
the common electrode is provided on the second electrodes of two or more of the light emitting elements, and
the insulating member covers a lateral surface of the organic layer of each of the light emitting elements.

An electronic device according to the present disclosure includes the display device according to the present disclosure.

In the display device according to the present disclosure, the insulating member may include a plurality of sidewalls, and each of the sidewalls may cover the lateral surface of a corresponding one of the light emitting elements, for example, the lateral surface of the organic layer included in the corresponding one of the light emitting elements.

In the display device according to the present disclosure, the insulating member may include an inter-element insulating layer provided between the light emitting elements adjacent to each other, and the inter-element insulating layer may cover the lateral surface of each of the light emitting elements, for example, the lateral surface of the organic layer included in each of the light emitting elements.

### BRIEF DESCRIPTION OF DRAWINGS

FIG. 1 is a schematic diagram illustrating an example of an overall configuration of a display device according to a first embodiment.

FIG. 2 is a cross-sectional view illustrating an example of a configuration of the display device according to the first embodiment.

FIGS. 3A, 3B, 3C, and 3D are each a process diagram for describing an example of a method of manufacturing the display device according to the first embodiment.

FIGS. 4A and 4B are each a process diagram for describing an example of the method of manufacturing the display device according to the first embodiment.

FIG. 5 is a cross-sectional view illustrating an example of a configuration of a display device according to a second embodiment.

FIGS. 6A and 6B are each a process diagram for describing an example of a method of manufacturing the display device according to the second embodiment.

FIGS. 7A, 7B, and 7C are each a process diagram for describing an example of the method of manufacturing the display device according to the second embodiment.

FIG. 8 is a cross-sectional view illustrating an example of a configuration of a display device according to a third embodiment.

FIGS. 9A and 9B are each a process diagram for describing an example of a method of manufacturing the display device according to the third embodiment.

FIGS. 10A, 10B, and 10C are each a process diagram for describing an example of the method of manufacturing the display device according to the third embodiment.

FIG. 11 is a cross-sectional view illustrating an example of a configuration of a display device according to a modification.

FIG. 12 is a cross-sectional view illustrating an example of a configuration of a display device according to a modification.

FIG. 13 is a cross-sectional view illustrating an example of a configuration of a display device according to a modification.

FIG. 14 is a cross-sectional view illustrating an example of a configuration of a display device according to a modification.

FIG. 15 is a cross-sectional view illustrating an example of a configuration of a display device according to a modification.

FIG. 16 is a cross-sectional view illustrating an example of a configuration of a display device according to a modification.

FIG. 17 is a cross-sectional view illustrating an example of a configuration of a display device according to a modification.

FIG. 18 is a cross-sectional view illustrating an example of a configuration of a display device according to a modification.

FIG. 19 is a cross-sectional view illustrating an example of a configuration of a display device according to a modification.

FIGS. 20A and 20B are each a plan view illustrating an example of a configuration of a display device according to a modification.

FIGS. 21A and 21B are each a plan view illustrating an example of a configuration of a display device according to a modification.

FIG. 22 is a plan view illustrating an example of a schematic configuration of a module.

FIG. 23A is a front view illustrating an example of an external appearance of a digital still camera. FIG. 23B is a rear view illustrating an example of the external appearance of the digital still camera.

FIG. 24 is a perspective view illustrating an example of an external appearance of a head mounted display.

FIG. 25 is a perspective view illustrating an example of an external appearance of a television device.

### MODE FOR CARRYING OUT THE INVENTION

Embodiments and examples of the present disclosure will be described in the following order. Note that the same or corresponding portions will be denoted by the same reference signs in all the drawings of the following embodiments.
1 First Embodiment (Example of Display Device)
2 Second Embodiment (Example of Display Device)
3 Third Embodiment (Example of Display Device)
4 Modification (Modification of Display Device)
5 Application Example (Example of Electronic Device)

### 1 First Embodiment

### [Configuration of Display Device 10]

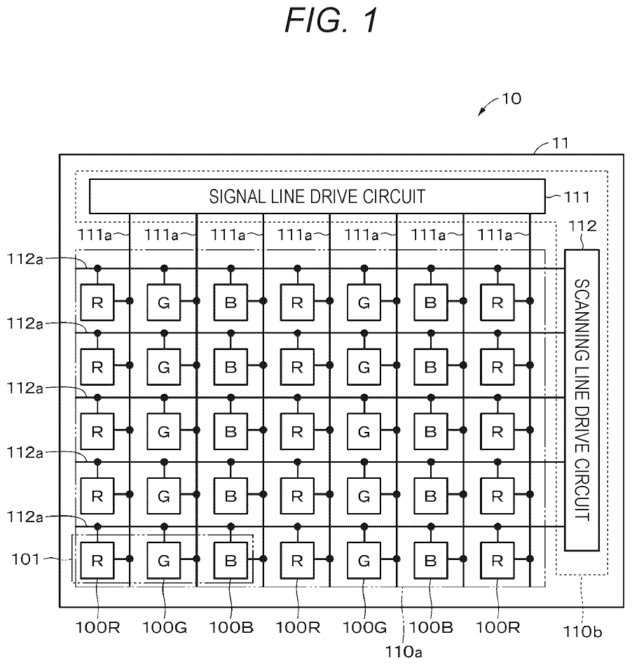

FIG. 1 is a schematic diagram illustrating an example of an overall configuration of a display device 10 according to a first embodiment. The display device 10 is an OLED display device, and includes a display region 110a and a peripheral region 110b provided adjacent to a peripheral edge of the display region 110a. In the display region 110a, a plurality of sub-pixels 100R, 100G, and 100B is two-dimensionally arranged in a prescribed arrangement pattern such as a delta pattern or a matrix pattern. Note that FIG. 1 illustrates an example where the plurality of sub-pixels 100R, 100G, and 100B is two-dimensionally arranged in a matrix pattern.

The sub-pixel 100R can display red. The sub-pixel 100G can display green. The sub-pixel 100B can display blue. Red is an example of a first primary color among the three primary colors. Green is an example of a second primary color among the three primary colors. Blue is an example of a third primary color among the three primary colors. Note that, in the following description, the sub-pixels 100R, 100G, and 100B are collectively referred to as sub-pixel 100 unless otherwise distinguished. A combination of three sub-pixels 100R, 100G, and 100B adjacent to each other in a horizontal direction (row direction) of a display surface constitutes one pixel (pixel) 101. FIG. 1 illustrates an example where the combination of three sub-pixels 100R, 100G, and 100B adjacent to each other in the horizontal direction (row direction) constitutes one pixel 101, but the pixel 101 is not limited to such a configuration. The sub-pixels 100R, 100G, and 100B each have, for example, a quadrilateral shape such as a rectangular shape in plan view. In the present specification, the rectangular shape includes a square shape. In the present specification, the plan view means a plan view when an object is viewed from a direction perpendicular to the display surface of the display device 10.

In the peripheral region 110b, a signal line drive circuit 111 and a scanning line drive circuit 112, which are drivers for video display, are provided. The signal line drive circuit 111 supplies a signal voltage of a video signal corresponding to luminance information supplied from a signal supply source (not illustrated) to the sub-pixel 100 selected via a signal line 111a. The scanning line drive circuit 112 includes, for example, a shift register or the like that sequentially shifts (transfers) a start pulse in synchronization with an input clock pulse. The scanning line drive circuit 112 scans the sub-pixels 100 row by row at the time of writing the video signal to each sub-pixel 100, and sequentially supplies a scanning signal to each scanning line 112a.

The display device 10 is an example of a light emitting device. The display device 10 is a top emission type OLED display device. The display device 10 may be a microdisplay. The display device 10 may be provided in a virtual reality (VR) device, a mixed reality (MR) device, an augmented reality (AR) device, an electronic view finder (EVF), a small projector, or the like.

In the following description, in each layer constituting the display device 10, a surface on the top side (display surface side) of the display device 10 is referred to as first surface, and a surface on the bottom side (side opposite to the display surface) of the display device 10 is referred to as second surface.

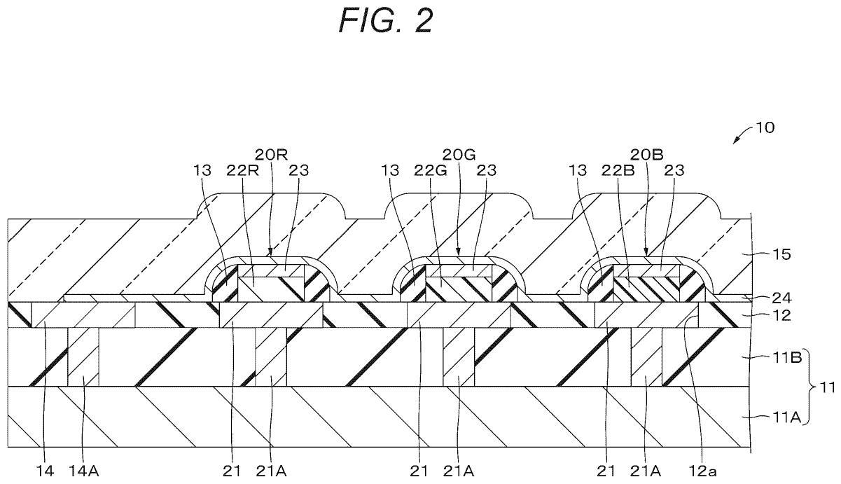

FIG. 2 is a cross-sectional view illustrating an example of a configuration of the display device 10 according to the first embodiment. The display device 10 includes a circuit board 11, a plurality of light emitting elements 20R, 20G, and 20B, a common electrode 24, an insulating layer 12, a plurality of sidewalls 13, a contact portion 14, and a protective layer 15. Note that, in the following description, the light emitting elements 20R, 20G, and 20B are collectively referred to as light emitting element 20 unless otherwise distinguished.

### (Circuit Board 11)

The circuit board 11 is what is called a backplane, and drives the plurality of light emitting elements 20. The circuit board 11 includes a substrate 11A and an insulating layer 11B. On the first surface of the circuit board 11, a drive circuit that drives the plurality of light emitting elements 20, a power supply circuit that supplies power to the plurality of light emitting elements 20, and the like (none of which is illustrated) are provided.

The substrate 11A may include, for example, a semiconductor in which a transistor or the like is easily formed, or may include glass or resin having low moisture and oxygen permeability. Specifically, the substrate 11A may be a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

The insulating layer 11B is provided on the first surface of the substrate 11A and covers the drive circuit, the power supply circuit, and the like. The insulating layer 11B includes a plurality of contact plugs 14A and a plurality of contact plugs 21A therein. The contact plugs 14A and the contact plugs 21A are connection members that electrically connect the light emitting elements 20 to the drive circuit and the like. The contact plugs 14A and the contact plugs 21A each include, for example, at least one selected from a group including copper (Cu), titanium (Ti), and the like.

The insulating layer 11B may be an organic insulating layer, an inorganic insulating layer, or a laminate of the organic insulating layer and the inorganic insulating layer. The organic insulating layer includes, for example, at least one selected from a group including a polyimide-based resin, an acrylic resin, a novolac-based resin, and the like. The inorganic insulating layer includes, for example, at least one selected from a group including silicon oxide (SiOₓ), silicon nitride (SiNₓ), silicon oxynitride (SiOₓN_{y}), and the like.

### (Light Emitting Element 20R, 20G, 20B)

The light emitting element 20R constitutes the sub-pixel 100R. The light emitting element 20G constitutes the sub-pixel 100G. The light emitting element 20B constitutes the sub-pixel 100B. The light emitting element 20R is a red OLED element, and can emit red light under the control of the drive circuit and the like. The light emitting element 20G is a green OLED element, and can emit green light under the control of the drive circuit and the like. The light emitting element 20B is a blue OLED element, and can emit blue light under the control of the drive circuit and the like. The OLED element of each color may be a micro-OLED (MOLED) element. The plurality of light emitting elements 20 is two-dimensionally arranged on the first surface of the circuit board 11 in a prescribed arrangement pattern such as a delta pattern or a matrix pattern.

The light emitting element 20R includes a first electrode 21, an OLED layer 22R, and a second electrode 23 in this order on the first surface of the circuit board 11. The light emitting element 20G includes the first electrode 21, an OLED layer 22G, and the second electrode 23 in this order on the first surface of the circuit board 11. The light emitting element 20B includes the first electrode 21, an OLED layer 22B, and the second electrode 23 in this order on the first surface of the circuit board 11. Note that, in the following description, the OLED layers 22R, 22G, and 22B are collectively referred to as OLED layer 22 unless otherwise distinguished.

### (First Electrode 21)

The first electrode 21 is an anode. When a voltage is applied between the first electrode 21 and the second electrode 23, holes are injected from the first electrode 21 into the OLED layer 22. The first electrode 21 is provided on the first surface of the circuit board 11. The first electrode 21 is isolated for each sub-pixel 100, that is, for each light emitting element 20.

The first electrode 21 may include, for example, a metal layer, or may include a metal layer and a transparent conductive oxide layer. In a case where the first electrode 21 includes a metal layer and a transparent conductive oxide layer, the transparent conductive oxide layer is preferably provided adjacent to the OLED layer 22 from the viewpoint of placing a layer having a high work function adjacent to the OLED layer 22.

The metal layer also has a function as a reflective layer that reflects light emitted from the OLED layer 22. The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

A base layer (not illustrated) may be provided adjacent to the second surface of the metal layer. The base layer is for improving the crystal orientation of the metal layer at the time of forming the metal layer. The base layer includes, for example, at least one metal element selected from a group including titanium (Ti) and tantalum (Ta). The base layer may include the at least one metal element described above as a constituent element of an alloy.

The transparent conductive oxide layer includes a transparent conductive oxide. The transparent conductive oxide includes, for example, at least one selected from a group including a transparent conductive oxide including indium (hereinafter referred to as “indium-based transparent conductive oxide”), a transparent conductive oxide including tin (hereinafter referred to as a “tin-based transparent conductive oxide”), and a transparent conductive oxide including zinc (hereinafter referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO) or fluorine-doped indium oxide (IFO). Among these transparent conductive oxides, the indium tin oxide (ITO) is particularly preferable. This is because the indium tin oxide (ITO) has a particularly low barrier for hole injection into the OLED layer 22 in terms of a work function, so that the drive voltage of the display device 10 can be particularly reduced. The tin-based transparent conductive oxide includes, for example, tin oxide, antimony-doped tin oxide (ATO), or fluorine-doped tin oxide (FTO). The zinc-based transparent conductive oxide includes, for example, zinc oxide, aluminum-doped zinc oxide (AZO), boron-doped zinc oxide, or gallium-doped zinc oxide (GZO).

### (OLED Layers 22R, 22G, 22B)

The OLED layer 22 is an example of an organic layer including a light emitting layer. The OLED layer 22R can emit red light by recombination of holes injected from the first electrode 21 and electrons injected from the second electrode 23. The OLED layer 22G can emit green light by recombination of holes injected from the first electrode 21 and electrons injected from the second electrode 23. The OLED layer 22B can emit blue light by recombination of holes injected from the first electrode 21 and electrons injected from the second electrode 23.

The OLED layer 22 is isolated for each sub-pixel 100, that is, for each light emitting element 20. The OLED layers 22R, 22G, and 22B are included in the light emitting elements 20R, 20G, and 20B, respectively. The OLED layer 22 is provided on the first surface of the first electrode 21. A peripheral edge of the OLED layer 22 is located inside a peripheral edge of the first electrode 21. A peripheral edge portion of the first surface of the first electrode 21 is exposed without being covered with the OLED layer 22. In the present specification, the peripheral edge portion of the first surface refers to a region having a predetermined width from the peripheral edge of the first surface toward the inside.

The OLED layer 22R includes, for example, a hole injection layer, a hole transport layer, a red light emitting layer, an electron transport layer, and an electron injection layer in this order on the first surface of the first electrode 21. The OLED layer 22G includes, for example, a hole injection layer, a hole transport layer, a green light emitting layer, an electron transport layer, and an electron injection layer in this order on the first surface of the first electrode 21. The OLED layer 22B includes, for example, a hole injection layer, a hole transport layer, a blue light emitting layer, an electron transport layer, and an electron injection layer in this order on the first surface of the first electrode 21.

The hole injection layer is for enhancing efficiency of hole injection into each light emitting layer and suppressing leakage. The hole transport layer is for enhancing efficiency of hole transport to each light emitting layer. The electron injection layer is for enhancing efficiency of electron injection into each light emitting layer. The electron transport layer is for enhancing efficiency of electron transport to each light emitting layer.

When a voltage is applied between the first electrode 21 and the second electrode 23, the red light emitting layer, the green light emitting layer, and the blue light emitting layer can emit red light, green light, and blue light, respectively, by recombination of holes injected from the first electrode 21 and electrons injected from the second electrode 23.

### (Second Electrode 23)

The second electrode 23 is a cathode. When a voltage is applied between the first electrode 21 and the second electrode 23, electrons are injected from the second electrode 23 into the OLED layer 22. The second electrode 23 is a transparent electrode having transparency to visible light. The second electrode 23 transmits light emitted from the OLED layer 22. In the present specification, visible light refers to light in a wavelength range of from 360 nm or more to 830 nm.

The second electrode 23 is isolated for each sub-pixel 100, that is, for each light emitting element 20. The second electrode layer 23 is provided on the first surface of the OLED layer 22. A lateral surface of the second electrode 23 may be flush with a lateral surface of the OLED layer 22.

The second electrode 23 preferably includes a material having as high transmissivity as possible and a small work function, in order to enhance luminous efficiency. The second electrode 23 includes, for example, at least one of a metal layer or a transparent conductive oxide layer. More specifically, the second electrode 23 includes a single layer film of a metal layer or a transparent conductive oxide layer, or a laminated film of the metal layer and the transparent conductive oxide layer. In a case where the second electrode 23 includes a laminated film of the metal layer and the transparent conductive oxide layer, the metal layer may be provided adjacent to the OLED layer 22, or the transparent conductive oxide layer may be provided adjacent to the OLED layer 22, but from the viewpoint of preventing oxidation of the first surface of the second electrode 23, the metal layer is preferably provided adjacent to the OLED layer 22.

The metal layer includes, for example, at least one metal element selected from a group including magnesium (Mg), aluminum (Al), silver (Ag), calcium (Ca), and sodium (Na). The metal layer may include the at least one metal element described above as a constituent element of an alloy. Specific examples of the alloy include an MgAg alloy, an MgAl alloy, an AlLi alloy, and the like. The transparent conductive oxide layer includes a transparent conductive oxide. As the transparent conductive oxide, a material similar to the transparent conductive oxide of the first electrode 21 described above can be exemplified.

### (Insulating Layer 12)

The insulating layer 12 provides insulation between the first electrodes 21 isolated from each other. The insulating layer 12 is provided in a portion between the first electrodes 21 isolated from each other on the first surface of the circuit board 11. The insulating layer 12 has a plurality of openings 12a. Each of the plurality of openings 12a is provided for a corresponding one of light emitting elements 20. Each first electrode 21 is provided in a corresponding opening 12a to have its lateral surface covered with the insulating layer 12. The first surface of the first electrode 21 and the first surface of the insulating layer 12 may be almost the same in height as each other. Here, the height of the first surface of the first electrode 21 and the height of the first surface of the insulating layer 12 mean a position in a thickness direction of the display device 10 relative the first surface of the substrate 11A. In the present specification, the expression of almost the same includes the meaning of the same. Each opening 12a may be provided on the first surface of the first electrode 21. That is, the peripheral edge portion of the first surface of each first electrode 21 may be covered with the insulating layer 12.

The insulating layer 12 may be an organic insulating layer, an inorganic insulating layer, or a laminate of the organic insulating layer and the inorganic insulating layer. The organic insulating layer includes, for example, at least one selected from a group including a polyimide-based resin, an acrylic resin, a novolac-based resin, and the like. The inorganic insulating layer includes, for example, at least one selected from a group including silicon oxide (SiOₓ), silicon nitride (SiNₓ), silicon oxynitride (SiOₓN_{y}), and the like.

### (Sidewall 13)

The sidewall 13 has insulating properties. The sidewall 13 is an example of an insulating member. The sidewall 13 provides insulation between the peripheral edge portion of the first surface of the first electrode 21 and the second surface of the common electrode 24. The sidewall 13 provides insulation between the lateral surface of the OLED layer 22 and the second surface of the common electrode 24, and provides insulation between the lateral surface of the second electrode 23 and the second surface of the common electrode 24. The sidewall 13 may be lower in refractive index than the OLED layer 22.

The sidewall 13 covers the lateral surface of the OLED layer 22 and the lateral surface of the second electrode 23. The sidewall 13 has a closed loop shape in plan view and surrounds the light emitting element 20. In the present specification, the plan view means a plan view when an object is viewed from a direction perpendicular to the display surface of the display device 10.

A top portion of the sidewall 13 and the first surface of the second electrode 23 may be almost the same in height as each other. Here, the height of the top portion of the sidewall 13 and the height of the first surface of the second electrode 23 mean a position in the thickness direction of the display device 10 relative to the first surface of the first electrode 21. The top portion of the sidewall 13 is a convex curved surface that rises from the outer periphery of the sidewall 13 toward the inner periphery of the sidewall 13.

The sidewall 13 is provided on the first surface of the first electrode 21 and the first surface of the insulating layer 12 so as to extend across a boundary between the first electrode 21 and the insulating layer 12. An inner periphery of a bottom surface of the sidewall 13 is located inside the peripheral edge of the first electrode 21, and an outer periphery of the bottom surface of the sidewall 13 is located outside a peripheral edge of the insulating layer 12. That is, the inner periphery of the bottom surface of the sidewall 13 is located on the first surface of the first electrode 21, and the outer periphery of the bottom surface of the sidewall 13 is located on the first surface of the insulating layer 12.

The sidewall 13 includes an insulating material. The insulating material includes, for example, at least one selected from a group including silicon oxide (SiOₓ), silicon nitride (SiNₓ), silicon oxynitride (SiOₓN_{y}), and the like.

### (Contact Portion 14)

The contact portion 14 is an auxiliary electrode that connects the common electrode 24 to a base wiring and the like (not illustrated). The first surface of the contact portion 14 is electrically connected to a peripheral edge portion of the second surface of the common electrode 24. On the other hand, the second surface of the contact portion 14 is connected to the base wiring and the like via the plurality of contact plugs 14A. In the present specification, the peripheral edge portion of the second surface of the common electrode 24 refers to a region having a predetermined width from the peripheral edge of the second surface of the common electrode 24 toward the inside.

The contact portion 14 is provided adjacent to the peripheral edge portion of the display region 110a on the first surface of the circuit board 11. The contact portion 14 may have a closed-loop shape surrounding the display region 110a, or may be provided to face a part of the outer periphery of the display region 110a.

The contact portion 14 includes, for example, at least one of a metal layer or a metal oxide layer. More specifically, the contact portion 14 includes, for example, a single layer film of a metal layer or a metal oxide layer, or a laminated film of the metal layer and the metal oxide layer. The contact portion 14 is preferably similar in configuration to the first electrode 21. In this case, since the contact portion 14 can be formed simultaneously with the first electrode 21, the process of manufacturing the display device 10 can be simplified.

As a constituent material of the contact portion 14, a material similar to the material of the first electrode 21 can be exemplified. Specifically, as constituent materials of the metal layer and the metal oxide layer of the contact portion 14, materials similar to the materials of the metal layer and the metal oxide layer of the first electrode 21 can be exemplified, respectively.

### (Common Electrode 24)

The common electrode 24 is a cathode common to the plurality of sub-pixels 100, that is, the plurality of light emitting elements 20. The common electrode 24 electrically connects the second electrode 23 of each of the plurality of light emitting elements 20 included in the display region 110a to the contact portion 14. The second electrode 23 is a transparent electrode having transparency to visible light. The second electrode 23 transmits light emitted from the light emitting element 20.

The common electrode 24 is provided across the plurality of sub-pixels 100, that is, the plurality of light emitting elements 20 in the display region 110a, and is shared by the plurality of sub-pixels 100 in the display region 110a. The common electrode 24 is electrically connected to the first surface of the second electrode 23 included in each of the plurality of light emitting elements 20, and is electrically connected to the first surface of each of the plurality of contact portions 14. The common electrode 24 is preferably in contact with all of the first surface of the second electrode 23 from the viewpoint of reducing connection resistance between the common electrode 24 and the second electrode 23. The contact portion 14 is preferably in contact with all of the first surface of the second electrode 23 from the viewpoint of reducing connection resistance between the common electrode 24 and the contact portion 14.

A plurality of structures including the light emitting element 20 and the sidewall 13 is provided on the first surface of the circuit board 11. The common electrode 24 is provided on the first surface of the circuit board 11 so as to follow the plurality of structures. The common electrode 24 covers the sidewall 13. The common electrode 24 is provided on the first surface of the insulating layer 12 between the light emitting elements 20 isolated from each other.

The second electrode 23 includes, for example, a metal layer or a transparent conductive oxide layer. The second electrode 23 may be a laminate of the metal layer and the transparent conductive oxide layer. The metal layer includes metal. As the metal layer, a material similar to the material of the second electrode 23 described above can be exemplified. The metal layer may include an alloy. As the alloy, a material similar to the material of the second electrode 23 described above can be exemplified. The transparent conductive oxide layer includes a transparent conductive oxide. As the transparent conductive oxide, a material similar to the transparent conductive oxide of the first electrode 21 described above can be exemplified.

### (Protective Layer 15)

The protective layer 15 protects the plurality of light emitting elements 20 and the common electrode 24. The protective layer 15 has transparency to visible light. The protective layer 15 is provided on the first surface of the common electrode 24 to cover the plurality of light emitting elements 20. The protective layer 15 shields the common electrode 24 and the plurality of light emitting elements 20 from outside air to prevent moisture ingress into the common electrode 24 and the plurality of light emitting elements 20 from an external environment. Furthermore, in a case where the common electrode 24 includes a metal layer, the protective layer 15 may have a function of preventing oxidation of the metal layer.

The protective layer 15 includes, for example, an inorganic material or a polymer resin having low hygroscopicity. The protective layer 15 may have a single layer structure or a multilayer structure. In a case where a thickness of the protective layer 15 is increased, it is preferable that the protective layer 15 have a multilayer structure. This is for alleviating the internal stress in the protective layer 15. The inorganic material includes, for example, at least one selected from a group including silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one selected from a group including a thermosetting resin, an ultraviolet curable resin, and the like.

### [Method of Manufacturing Display Device 10]

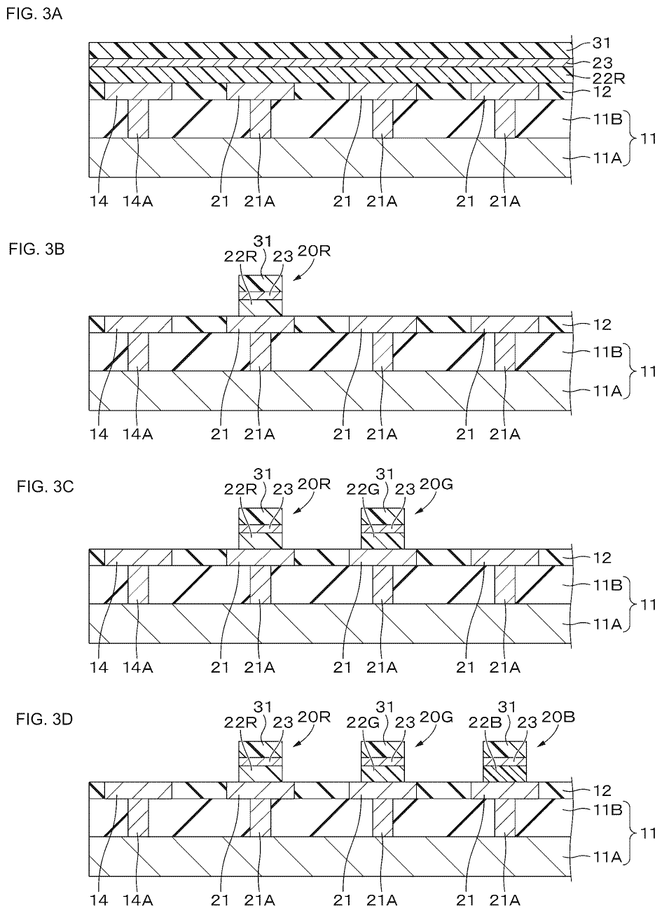

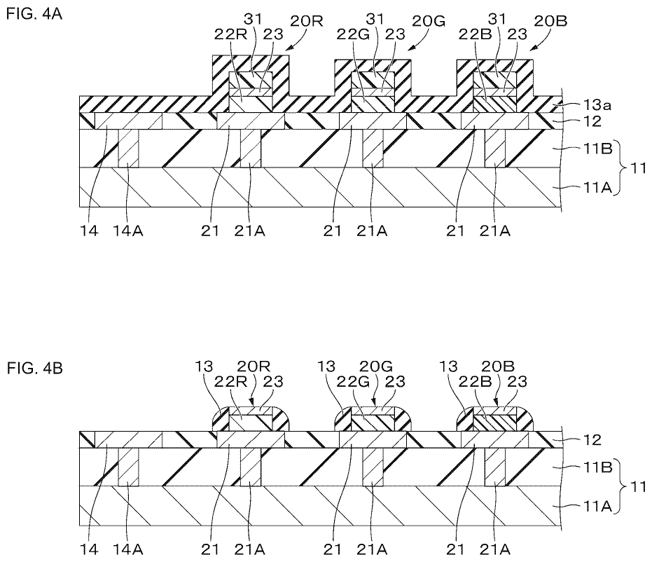

Hereinafter, an example of a method of manufacturing the display device 10 according to the first embodiment will be described with reference to FIGS. 3A to 3D, and FIGS. 4A and 4B.

### (Process of Forming First Electrode 21 or Contact Portion 14)

First, a metal layer and a metal oxide layer are sequentially formed on the first surface of the circuit board 11 by, for example, a vapor deposition method or a sputtering method, and then the metal layer and the metal oxide layer are patterned using, for example, a photolithography technique and an etching technique. As a result, the plurality of first electrodes 21 and the plurality of contact portions 14 are formed on the first surface of the circuit board 11.

### (Process of Forming Insulating Layer 12)

Next, the insulating layer 12 is formed on the first surface of the circuit board 11 to cover the plurality of first electrodes 21 and the plurality of contact portions 14 by, for example, a chemical vapor deposition (CVD) method. Next, the first surface of each first electrode 21 is exposed by, for example, an etch-back method.

### (Process of Forming Light Emitting Element 20R)

Next, the OLED layer 22R is formed on the first surface of each of the plurality of first electrodes 21 and the first surface of the insulating layer 12 by, for example, a vapor deposition method. Next, the second electrode 23 is formed on the first surface of the OLED layer 22R by, for example, a vapor deposition method or a sputtering method. Next, a resist layer 31 is formed on the first surface of the second electrode 23 by, for example, a spin coating method. As a result, as illustrated in FIG. 3A, a laminate of the OLED layer 22R, the second electrode 23, and the resist layer 31 is formed on the first surface of each of the plurality of first electrodes 21 and the first surface of the insulating layer 12.

Next, as illustrated in FIG. 3B, a laminate to be a formation position of the light emitting element 20R is left on the first surface of each corresponding first electrode 21, and the other laminate is removed by, for example, a photolithography technique and an etching technique (for example, dry etching or wet etching). As a result, the plurality of light emitting elements 20R is formed on the first surface of the circuit board 11. Note that the resist layer 31 remains on the first surface of each light emitting element 20R.

### (Process of Forming Light Emitting Element 20G)

Next, as illustrated in FIG. 3C, the plurality of light emitting elements 20G is formed on the first surface of the circuit board 11 in a manner similar to the process of forming the light emitting element 20R except that the OLED layer 22G is formed instead of the OLED layer 22R, and a laminate to be a formation position of the light emitting element 20G is left on the first surface of each corresponding first electrode 21, and the other laminate is removed. Note that the resist layer 31 remains on the first surface of each light emitting element 20G.

### (Process of Forming Light Emitting Element 20B)

Next, as illustrated in FIG. 3D, the plurality of light emitting elements 20G is formed on the first surface of the circuit board 11 in a manner similar to the process of forming the light emitting element 20R except that the OLED layer 22B is formed instead of the OLED layer 22R, a laminate to be a formation position of the light emitting element 20B is left on the first surface of each corresponding first electrode 21, and the other laminate is removed. Note that the resist layer 31 remains on the first surface of each light emitting element 20B.

### (Process of Forming Sidewall 13)

Next, as illustrated in FIG. 4A, an insulating layer 13a is formed on the first surface of the circuit board 11 so as to follow the plurality of light emitting elements 20 by, for example, a CVD method. Next, the insulating layer 13a and the resist layer 31 on the first surface of each light emitting element 20 are removed by, for example, an etch-back method to expose the first surface of the second electrode 23 of each light emitting element 20. At this time, the use of a highly anisotropic etching method allows the resist layer 31 on the first surface of the second electrode 23 to be removed and allows the insulating layer 13a around the lateral surface of the OLED layer 22 and the lateral surface of the second electrode 23 to be left. As a result, as illustrated in FIG. 4B, the sidewall 13 covering the lateral surface of the OLED layer 22 and the lateral surface of the second electrode 23 is formed for each light emitting element 20.

### (Process of Forming Common Electrode 24)

Next, the common electrode 24 is formed on the first surface of the circuit board 11 so as to follow each light emitting element 20 by, for example, a vapor deposition method or a sputtering method.

### (Process of Forming Protective Layer 15)

Next, the protective layer 15 is formed on the first surface of the common electrode 24 as a passivation layer by, for example, a CVD method or a vapor deposition method. As a result, the display device 10 illustrated in FIG. 2 is obtained.

### Action and Effect

In the display device 10 according to the first embodiment, the sidewall 13 as an insulating member covers the lateral surface of the OLED layer (organic layer including the light emitting layer) 22. This makes it possible to prevent the common electrode 24 from coming into contact with the lateral surface of the OLED layer 22. Furthermore, the sidewall 13 as an insulating member covers the peripheral edge portion of the first surface of the first electrode 21. This makes it possible to prevent the common electrode 24 from coming into contact with the peripheral edge portion of the first surface of first electrode 21. It is therefore possible to prevent the first electrode 21 and the common electrode 24 from being short-circuited. Furthermore, it is possible to prevent abnormal light emission on the lateral surface of the OLED layer 22.

Furthermore, as described above, since the sidewall 13 as an insulating member covers the lateral surface of the OLED layer 22, it is possible to prevent degradation of the lateral surface of the OLED layer 22 due to moisture or the like during the process of manufacturing the display device 10. It is therefore possible to prevent a decrease in display quality of the display device 10.

It is also possible to provide an insulating layer between the second electrode 23 and the common electrode 24 and electrically connect the second electrode 23 to the common electrode 24 via a via extending through the insulating layer. Since such a configuration causes the second electrode 23 and the common electrode 24 to electrically connect to each other via the via, the connection resistance between the second electrode 23 and the common electrode 24, however, depends on a contact area between the via and the second electrode 23 and a contact area between the via and the common electrode 24. Therefore, there is a possibility of causing an increase in the connection resistance between second electrode 23 and the common electrode 24.

On the other hand, in the display device 10 according to the first embodiment, no insulating layer is provided between the second electrode 23 and the common electrode 24, and the second electrode 23 and the common electrode 24 are directly connected to each other, so that it is possible to make the contact area between the second electrode 23 and the common electrode 24 large enough. It is therefore possible to reduce the connection resistance between second electrode 23 and the common electrode 24. This in turn allows a sufficient current to be supplied to the light emitting element 20 to increase luminous intensity of the light emitting element 20.

Since the OLED layer 22 is isolated between the sub-pixels 100 adjacent to each other, it is possible to prevent current leakage between the sub-pixels 100 adjacent to each other. It is therefore possible to increase luminous efficiency.

Since the OLED layer 22 is provided inside the peripheral edge of the first surface of the first electrode 21, it is possible to prevent the OLED layer 22 from bending to follow the lateral surface of the first electrode 21, the lateral surface of the insulating layer 12, and the like. It is therefore possible to prevent abnormal light emission of the OLED layer 22 due to the bending portion.

### 2 Second Embodiment

### [Configuration of Display Device 10A]

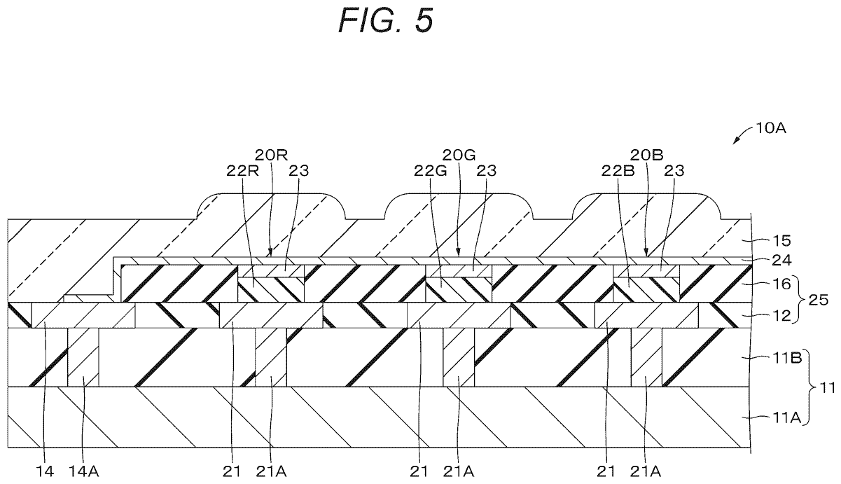

FIG. 5 is a cross-sectional view illustrating an example of a configuration of a display device 10A according to a second embodiment. The display device 10A is different from the display device 10 according to the first embodiment in that an insulating layer 16 is provided instead of the sidewall 13 (see FIG. 2).

The insulating layer 16 is provided between the light emitting elements 20 adjacent to each other. The insulating layer 16 is provided on the first surface of the insulating layer 12 and on the peripheral edge portion of the first surface of the first electrode 21. The insulating layer 16 has a plurality of openings 16a. Each of the plurality of openings 16a is provided for a corresponding one of the light emitting elements 20. Each OLED layer 22 is provided in a corresponding opening 16a to cause the lateral surface of the OLED layer 22 to be covered with the insulating layer 16. Furthermore, each second electrode 23 is provided in a corresponding opening 16a to cause the lateral surface of the second electrode 23 to be covered with the insulating layer 16. An inter-element insulating layer (first insulating layer) 25 that provides insulation between the light emitting elements 20 adjacent to each other includes the insulating layer 12 and the insulating layer 16.

It is preferable that the first surface of the insulating layer 16 be almost the same in height as the first surface of the first surface (top portion) of the light emitting element 20. This allows the first surface of the insulating layer 16 and the first surface of the light emitting element 20 to form an almost flat surface and allows the common electrode 24 to be formed on the almost flat surface. It is therefore possible to prevent, even if the OLED layer 22 is isolated between the sub-pixels 100, the occurrence of steps on the common electrode 24. Here, the height of the first surface of the second electrode 23 and the height of the first surface of the insulating layer 16 mean a position in the thickness direction of the display device 10A relative to the first surface of the substrate 11A.

The insulating layer 16 may include a plurality of layers. The plurality of layers may be different from each other in at least one of refractive index or composition. The configuration where the plurality of layers is different from each other in at least one of refractive index or composition indicates that the plurality of layers is different in refractive index from each other, that the plurality of layers is different in composition from each other, or that the plurality of layers is different from each other in both refractive index and composition.

The insulating layer 16 may be an organic insulating layer, an inorganic insulating layer, or a laminate of the organic insulating layer and the inorganic insulating layer. As the material of the organic insulating layer and the inorganic insulating layer, a material similar to the material of the insulating layer 12 can be exemplified.

The common electrode 24 is provided on the first surface of the insulating layer 16 and the first surface of the second electrode 23. It is preferable that the common electrode 24 be an almost flat layer in the display region 110a.

### [Method of Manufacturing Display Device 10A]

Hereinafter, an example of a method of manufacturing the display device 10A according to the second embodiment will be described with reference to FIGS. 3A to 3D, FIGS. 6A and 6B, and FIGS. 7A to 7C.

(Process of forming first electrode 21 and contact portion 14, process of forming insulating layer 12, and process of forming light emitting elements 20R, 20G, and 20B)

First, as illustrated in FIGS. 3A to 3D, the process of forming the first electrode 21 and the contact portion 14, the process of forming the insulating layer 12, and the process of forming the light emitting elements 20R, 20G, and 20B are performed in a manner similar to the first embodiment. As a result, the plurality of light emitting elements 20R, the plurality of light emitting elements 20G, and the plurality of light emitting elements 20B are formed on the first surface of the circuit board 11. Note that the resist layer 31 remains on
the first surfaces of the light emitting elements 20G, the light emitting elements 20G, and the light emitting elements 20G.

### (Process of Forming Insulating Layer 16)

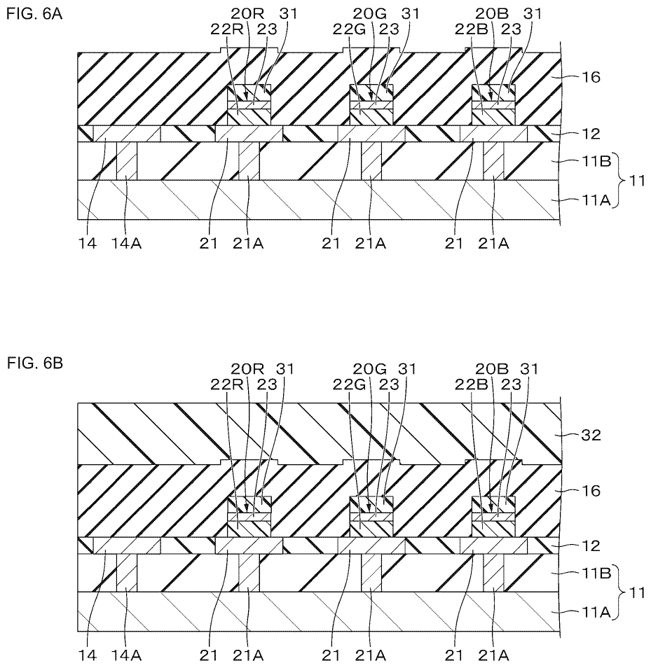

Next, as illustrated in FIG. 6A, the insulating layer 16 is formed on the first surface of the circuit board 11 by, for example, a CVD method. At this time, a film formation condition of the insulating layer 16 is set so that the thickness of the insulating layer 16 is larger than the total thickness of the OLED layer 22 and the second electrode 23.

### (Process of Forming Resist Layer 32)

Next, as illustrated in FIG. 6B, a resist layer 32 is formed on the first surface of the insulating layer 16 by, for example, a spin coating method. As a result, the resist layer 32 covers an uneven surface of the insulating layer 16 to from a flat surface. Note that, in the process of forming the insulating layer 16, in a case where the insulating layer 16 is thick enough to prevent the first surface of the insulating layer 16 from becoming uneven due to the shape of the plurality of light emitting elements 20, the process of forming the resist layer 32 may be omitted.

### (Process of Removing Resist Layer 32 and Insulating Layer 16)

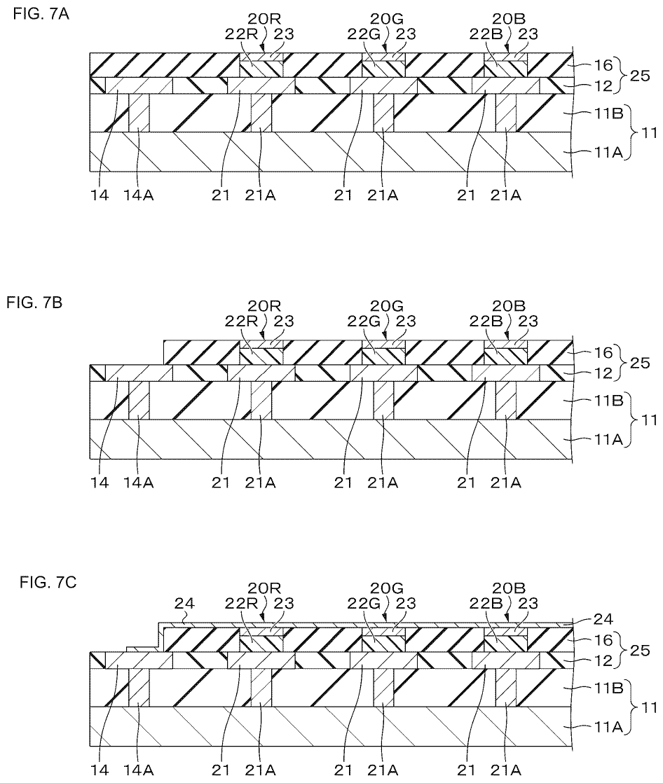

Next, as illustrated in FIG. 7A, the resist layer 32 and the insulating layer 16 are removed by, for example, an etch-back method until the first surface of the second electrode 23 is exposed. As a result, the first surface of the insulating layer 16 and the first surface of the light emitting element 20 form an almost flat surface.

### (Process of Exposing Contact Portion 14)

Next, as illustrated in FIG. 7B, the insulating layer 16 located on the contact portion 14 is removed by using, for example, a photolithography technique and an etching technique to expose the first surface of the contact portion 14 from the insulating layer 16.

### (Process of Forming Common Electrode 24)

Next, as illustrated in FIG. 7C, the common electrode 24 is formed all over the first surfaces of the plurality of light emitting elements 20, the first surface of the insulating layer 16, and the first surface of the contact portion 14 by, for example, a vapor deposition method or a sputtering method.

### (Process of Forming Protective Layer 15)

Next, the protective layer 15 is formed on the first surface of the common electrode 24 as a passivation layer by, for example, a CVD method or a vapor deposition method. As a result, the display device 10A illustrated in FIG. 5 is obtained.

### [Action and Effect]

Patent Document 1 discloses a technique for isolating an organic compound layer 22 including a light emitting layer between light emitting elements 20. However, when the organic compound layer 22 is isolated between the light emitting elements 20, a plurality of steps is generated on the surface of a substrate 10. When the plurality of steps is generated, a second upper electrode layer 27 is formed to follow the steps, and there is a possibility that the second upper electrode layer 27 breaks. Furthermore, there is also a possibility of causing an increase in connection distance between a wiring connection portion (contact portion) 24 and the light emitting pixel 20 due to the second upper electrode layer 27 (that is, an increase in resistance between the wiring connection portion 24 and the light emitting pixel 20). Therefore, there is a possibility that the display quality decreases.

On the other hand, in the display device 10A according to the second embodiment, since the inter-element insulating layer 25 is provided between the light emitting elements 20 adjacent to each other, the common electrode 24 can be made almost flat in the display region 110a. Therefore, even if the OLED layer 22 is isolated between the sub-pixels 100, it is possible to prevent the common electrode 24 from breaking and prevent an increase in connection distance between the contact portion 14 and the light emitting element 20 due to the common electrode 24 (that is, an increase in resistance between the contact portion 14 and the light emitting element 20). It is therefore possible to prevent a decrease in display quality.

### 3 Third Embodiment

### [Configuration of Display Device 10B]

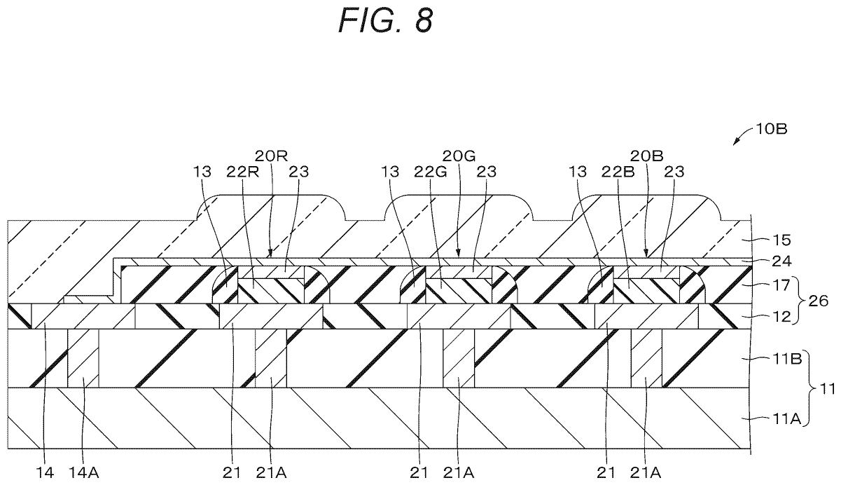

FIG. 8 is a cross-sectional view illustrating an example of a configuration of a display device 10B according to a third embodiment. The display device 10B is different from the display device 10 according to the first embodiment in that an insulating layer 17 is provided between the sidewalls 13 (see FIG. 2) of the light emitting elements 20 adjacent to each other.

The insulating layer 17 is provided on the first surface of the insulating layer 12. The insulating layer 17 covers the sidewall 13. An inter-element insulating layer (second insulating layer) 26 that provides insulation between the light emitting elements 20 adjacent to each other includes the insulating layer 12 and the insulating layer 17.

It is preferable that the first surface of the insulating layer 17 be almost the same in height as the first surface of the first surface (top portion) of the light emitting element 20. This allows the first surface of the insulating layer 17 and the first surface of the light emitting element 20 to form an almost flat surface and allows the common electrode 24 to be formed on the almost flat surface. It is therefore possible to prevent, even if the OLED layer 22 is isolated between the sub-pixels 100, the occurrence of steps on the common electrode 24. Here, the height of the first surface of the second electrode 23 and the height of the first surface of the insulating layer 17 mean a position in the thickness direction of the display device 10B relative to the first surface of the substrate 11A.

The sidewall 13 and the insulating layer 17 may be different from each other in at least one of refractive index or composition. The configuration where the sidewall 13 and the insulating layer 17 is different from each other in at least one of refractive index or composition indicates that the sidewall 13 and the insulating layer 17 are different in refractive index from each other, that the sidewall 13 and the insulating layer 17 is different in composition from each other, or that the sidewall 13 and the insulating layer 17 are different from each other in both refractive index and composition.

The insulating layer 17 may include a plurality of layers. The plurality of layers may be different from each other in at least one of refractive index or composition.

The common electrode 24 is provided on the first surface of the insulating layer 17 and the first surface of the second electrode 23. It is preferable that the common electrode 24 be an almost flat layer in the display region 110a.

### [Method of Manufacturing Display Device 10B]

Hereinafter, an example of a method of manufacturing the display device 10B according to the third embodiment will be described with reference to FIGS. 3A to 3D, FIGS. 4A and 4B, FIGS. 9A and 9B, and FIGS. 10A to 10C.

### (Process of Forming First Electrode 21 and Contact Portion 14, Process of Forming Insulating Layer 12, Process of Forming Light Emitting Elements 20R, 20G, 20B, and Process of Forming Sidewall 13)

First, as illustrated in FIGS. 3A to 3D, and FIGS. 4A and 4B, the process of forming the first electrode 21 and the contact portion 14, the process of forming the insulating layer 12, the process of forming the light emitting elements 20R, 20G, and 20B, and the process of forming the sidewall 13 are performed in a manner similar to the first embodiment. As a result, the plurality of light emitting elements 20R each having the sidewall 13, the plurality of light emitting elements 20G each having the sidewall 13, and the plurality of light emitting elements 20B each having the sidewall 13 are formed on the first surface of the circuit board 11.

### (Process of Forming Insulating Layer 16)

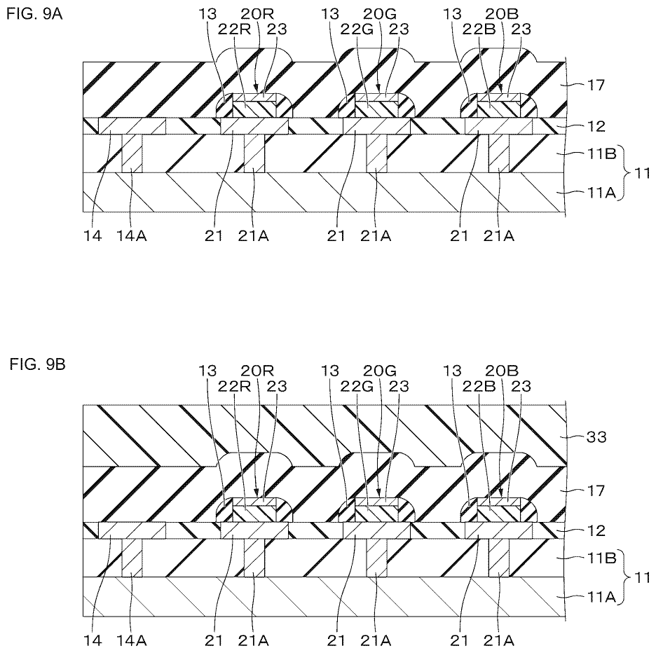

Next, as illustrated in FIG. 9A, the insulating layer 17 is formed on the first surface of the circuit board 11 by, for example, a CVD method. At this time, a film formation condition of the insulating layer 17 is set so that the thickness of the insulating layer 17 is larger than the total thickness of the OLED layer 22 and the second electrode 23.

### (Process of Forming Resist Layer 33)

Next, as illustrated in FIG. 9B, a resist layer 33 is formed on the first surface of the insulating layer 17 by, for example, a spin coating method. As a result, the resist layer 33 covers an uneven surface of the insulating layer 17 to form a flat surface. Note that, in the process of forming the insulating layer 17, in a case where the insulating layer 17 is thick enough to prevent the first surface of the insulating layer 17 from becoming uneven due to the shape of the plurality of light emitting elements 20, the process of forming the resist layer 33 may be omitted.

### (Process of Removing Resist Layer 32 and Insulating Layer 17)

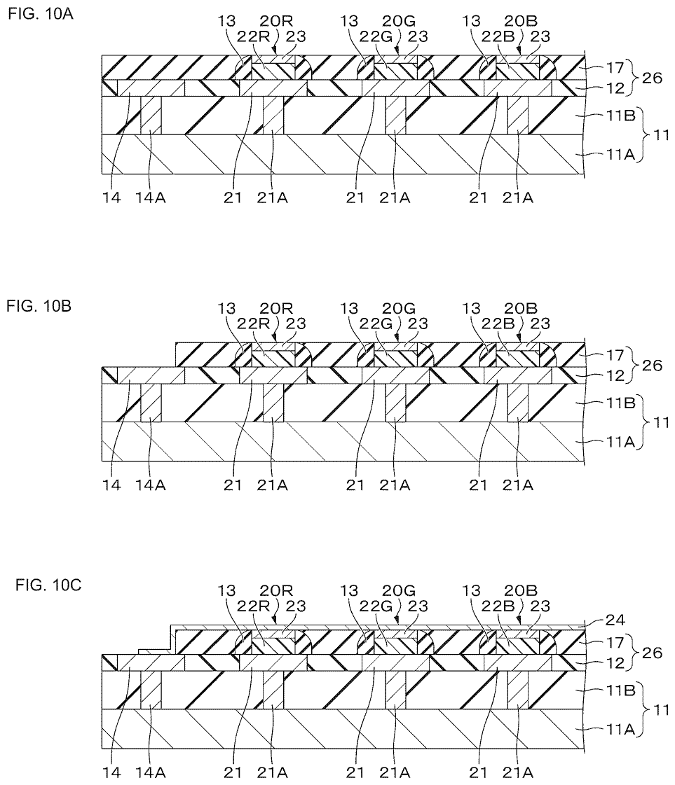

Next, as illustrated in FIG. 10A, the resist layer 33 and the insulating layer 17 are removed by, for example, an etch-back method until the first surface of the second electrode 23 is exposed. As a result, the first surface of the insulating layer 17 and the first surface of the light emitting element 20 form an almost flat surface.

### (Process of Exposing Contact Portion 14)

Next, as illustrated in FIG. 10B, the insulating layer 17 located on the contact portion 14 is removed by using, for example, a photolithography technique and an etching technique to expose the first surface of the contact portion 14 from the insulating layer 17.

### (Process of Forming Common Electrode 24)

Next, as illustrated in FIG. 10C, the common electrode 24 is formed all over the first surfaces of the plurality of light emitting elements 20, the first surface of the insulating layer 17, and the first surface of the contact portion 14 by, for example, a vapor deposition method or a sputtering method.

### (Process of Forming Protective Layer 15)

Next, the protective layer 15 is formed on the first surface of the common electrode 24 as a passivation layer by, for example, a CVD method or a vapor deposition method. As a result, the display device 10B illustrated in FIG. 8 is obtained.

### Action and Effect

In the display device 10B according to the third embodiment, since the inter-element insulating layer 26 is provided between the light emitting elements 20 adjacent to each other, it is possible to obtain an action and effect similar to the action and effect produced by the display device 10A according to the second embodiment.

### 4 Modification

### First Modification

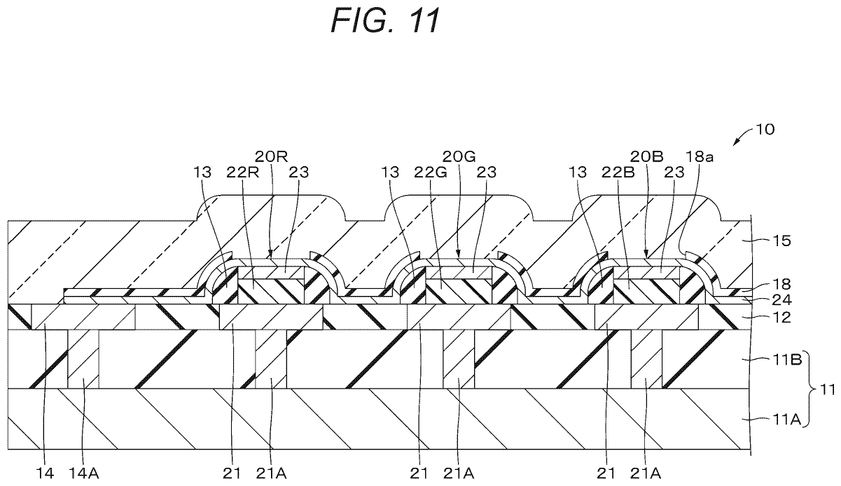

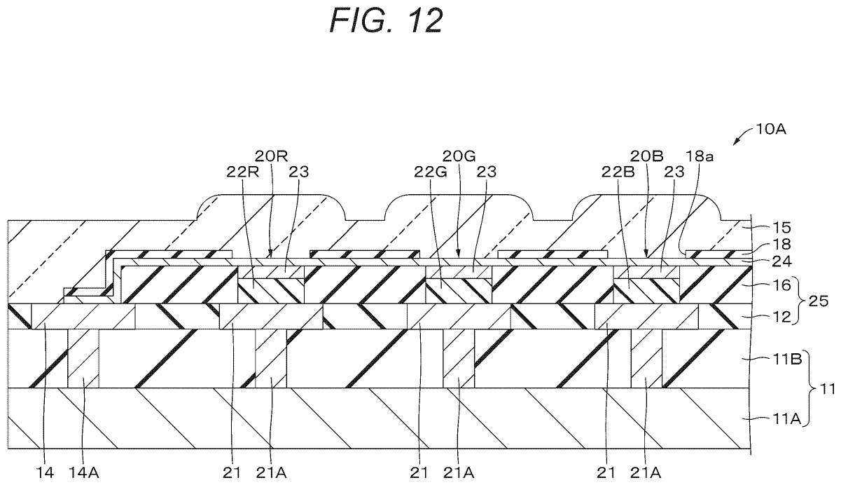

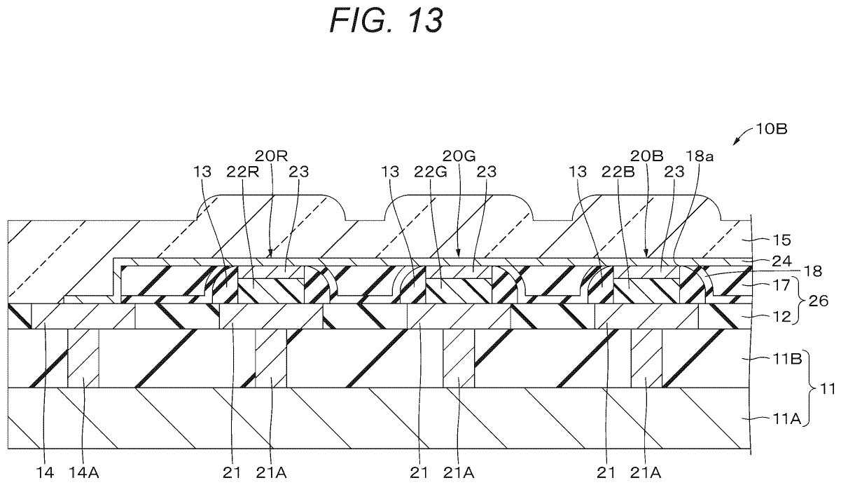

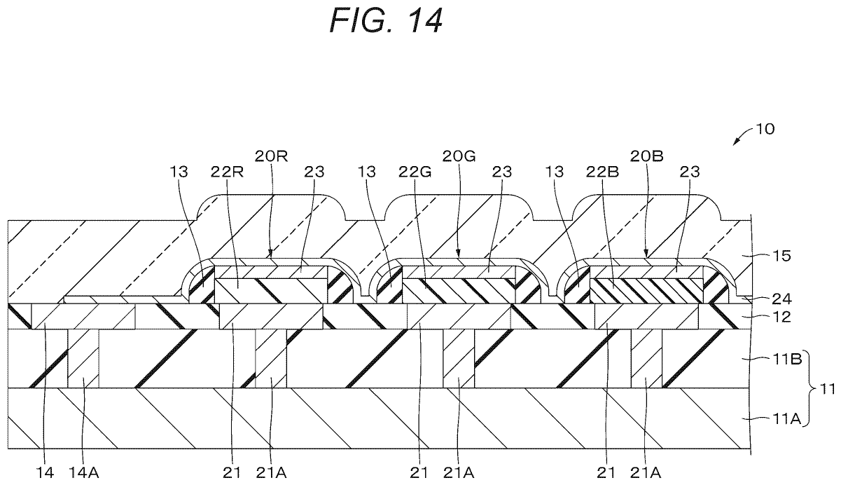

As illustrated in FIG. 11, the display device 10 according to the first embodiment may further include a light shielding layer 18. The light shielding layer 18 absorbs and blocks light emitted from the light emitting element 20. Furthermore, the light shielding layer 18 absorbs and blocks external light incident on the display surface of the display device 10.

The light shielding layer 18 is provided on the first surface of the common electrode 24. The light shielding layer 18 follows the common electrode 24. The light shielding layer 18 has a plurality of openings 18a. Each opening 18a allows light emitted from the light emitting element 20 to pass therethrough. Each opening 18a is provided for a corresponding one of the light emitting elements 20. More specifically, each opening 18a is provided above the light emitting element 20. From the viewpoint of preventing light leakage to an adjacent sub-pixel 100, it is preferable that the light shielding layer 18 cover the sidewall 13. It is preferable that the light shielding layer 18 cover the contact portion 14. This allows the light shielding layer 18 to absorb external light directed toward the contact portion 14. It is therefore possible to prevent external light from being reflected off the contact portion 14.

FIG. 11 illustrates an example where the first surface of the contact portion 14 is partially covered with the light shielding layer 18, but from the viewpoint of preventing external light from being reflected off the contact portion 14, it is preferable that the first surface of the contact portion 14 is entirely covered with the light shielding layer 18.

The light shielding layer 18 includes, for example, a light absorbing material. The light absorbing material includes, for example, at least one selected from the group including a black resin material and a black metal-containing material. The black resin material includes, for example, a carbon material such as carbon black. The black resin material is specifically, for example, a black color resist. The black metal-containing material includes, for example, titanium nitride (TiNₓ) or the like.

In the display device 10 configured as described above, since the light shielding layer 18 is provided on the first surface of the common electrode 24, the light shielding layer 18 can be brought closer to the OLED layer 22. Furthermore, the light shielding layer 18 covers the sidewall 13 and is disposed between the light emitting elements 20 adjacent to each other. It is therefore possible to prevent light leakage to an adjacent sub-pixel 100.

On the other hand, in a display device in which the light shielding layer is disposed on the second surface of the counter substrate, the light shielding layer is separated apart from the light emitting element, so that it is difficult to prevent light leakage to an adjacent sub-pixel 100.

### Second Modification

As illustrated in FIG. 12, the display device 10A according to the second embodiment may further include the light shielding layer 18 on the first surface of the common electrode 24. This configuration can prevent light leakage to an adjacent sub-pixel 100. Similarly, the display device 10B according to the third embodiment may further include the light shielding layer 18 on the first surface of the common electrode 24. This configuration can prevent light leakage to an adjacent sub-pixel 100.

As illustrated in FIG. 13, the display device 10B according to the third embodiment may further include the light shielding layer 18 between the sidewall 13 and the insulating layer 17 and between the insulating layer 12 and the insulating layer 17. This configuration can also prevent light leakage to an adjacent sub-pixel 100. The display device 10B may include the light shielding layer 18 between the sidewall 13 and the insulating layer 17 and between the insulating layer 12 and the insulating layer 17, and may also include the light shielding layer 18 on the first surface of the common electrode 24.

### Third Modification

In the first to third embodiments, the example where the peripheral edge of the OLED layer 22 is located inside the peripheral edge of the first electrode 21 has been described, or alternatively, as illustrated in FIG. 14, the peripheral edge of the OLED layer 22 may be located outside the peripheral edge of the first electrode 21. This case allows an increase in aperture ratio of the display device 10.

The peripheral edge of the OLED layer 22 may almost coincide with the peripheral edge of the first electrode 21, and the lateral surface of the OLED layer 22 and the lateral surface of the first electrode 21 may be almost flush with each other. This case also allows an increase in aperture ratio of the display device 10.

### Fourth Modification

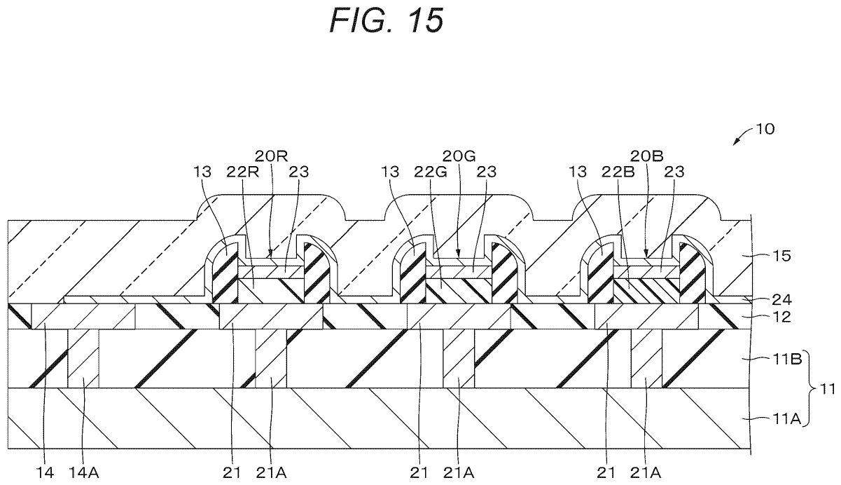

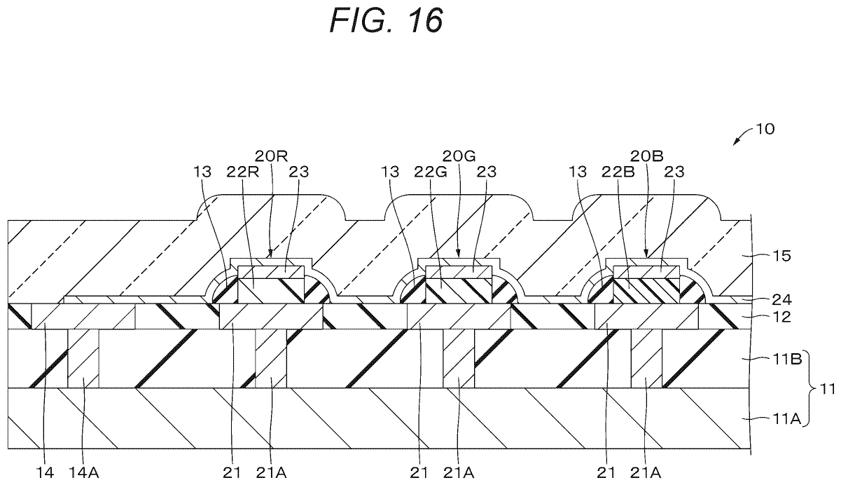

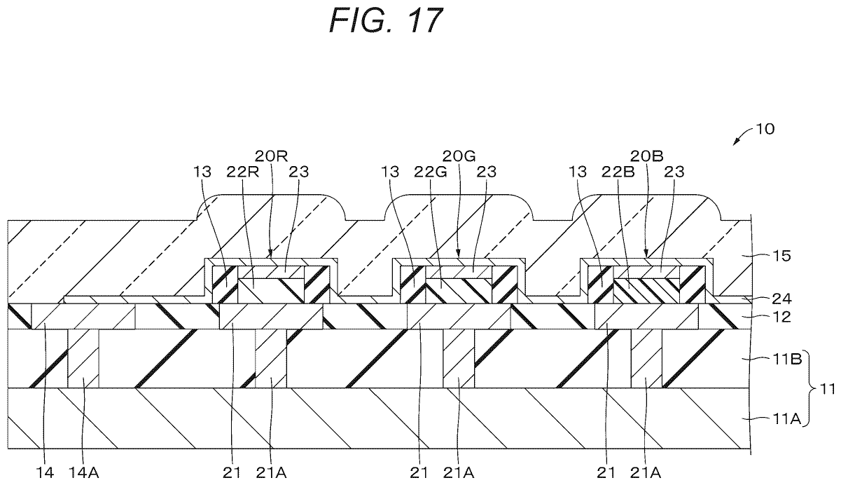

In the first embodiment, the example where the top portion of the sidewall 13 is almost the same in height as the first surface of the second electrode 23 has been described, or alternatively, as illustrated in FIG. 15, the top portion of the sidewall 13 may be higher in height than the first surface of the second electrode 23. Alternatively, as illustrated in FIG. 16, the top portion of the sidewall 13 may be lower in height than the first surface of the second electrode 23. In a case where the top portion of the sidewall 13 is lower in height than the first surface of the second electrode 23, the common electrode 24 is in contact with both the first surface of the second electrode 23 and the lateral surface of the second electrode 23, so that it is possible to reduce the connection resistance between the common electrode 24 and the second electrode 23.

### Fifth Modification

In the first embodiment, the example where the top portion of the sidewall 13 is a convex curved surface has been described, or alternatively, as illustrated in FIG. 17, the top portion of the sidewall 13 may be a flat surface parallel to the first surface of the first electrode 21. That is, the longitudinal cross section of the sidewall 13 may have a rectangular shape. Here, the longitudinal cross section indicates a cross section parallel to the thickness direction of the display device 10 and taken along the geometric center of the sub-pixel 100 in plan view.

### Sixth Modification

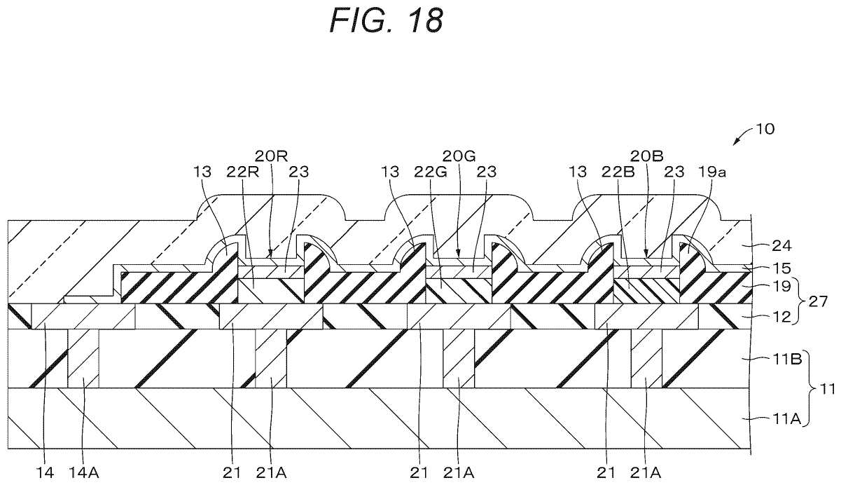

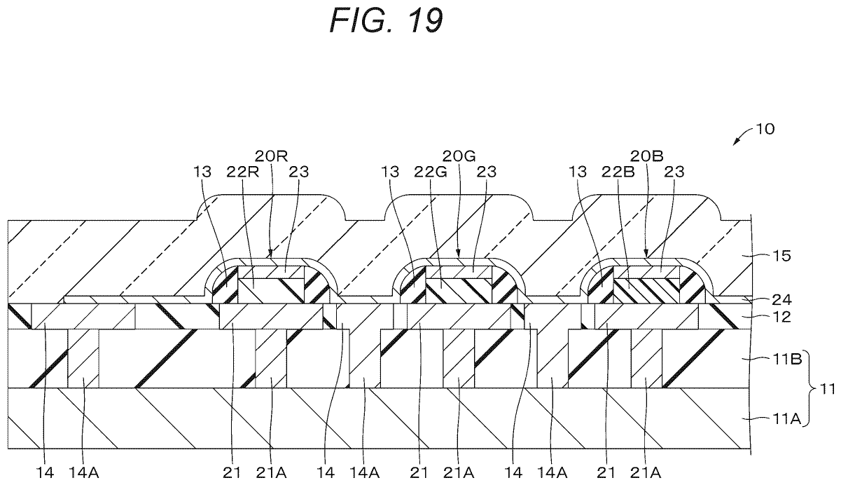

In the first embodiment, the example where the insulating member covering the lateral surface of the OLED layer 22 is the sidewall 13 has been described, or alternatively, as illustrated in FIG. 18, the insulating member may be an insulating layer 19. The insulating layer 19 may be provided on the peripheral edge portion of the first surface of the first electrode 21 and on the insulating layer 12. The insulating layer 19 may have a protruding portion 19a protruding relative to the first surface of the second electrode 23 at the peripheral edge of the light emitting element 20. An inter-element insulating layer (first insulating layer) 27 that provided insulation between the light emitting elements 20 adjacent to each other may include the insulating layer 12 and the insulating layer 19.

### Seventh Modification

In the first to third embodiments, the example where the plurality of contact portions 14 is provided in the peripheral edge portion of the display region 110a on the first surface of the circuit board 11, but how the plurality of contact portions 14 is arranged is not limited to such an arrangement. For example, as illustrated in FIG. 19, some of the plurality of contact portions 14 may be provided in the peripheral edge portion of the display region 110a on the first surface of the circuit board 11, and the rest may be provided in the display region 110a on the first surface of the circuit board 11. Alternatively, the plurality of contact portions 14 may be provided in the display region 110a on the first surface of the circuit board 11. The first surface of the contact portion 14 provided in the display region 110a is electrically connected to the common electrode 24 in the display region 110a.

### Eighth Modification

The configuration of the pixel 101 is not particularly limited to the configuration exemplified in the first embodiment.

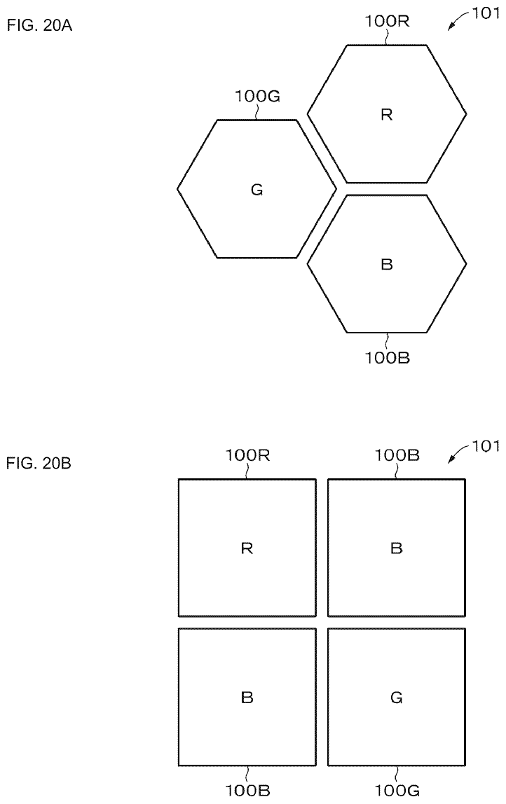

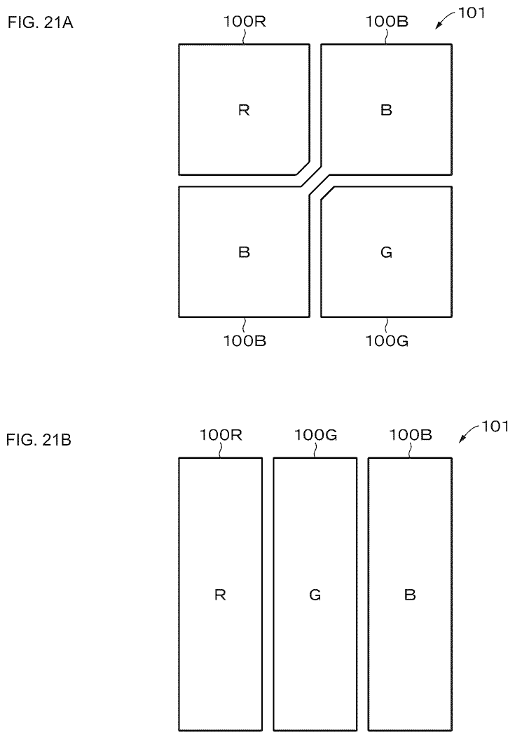

For example, as illustrated in FIG. 20A, three sub-pixels 100R, 100G, and 100B each having a hexagonal shape in plan view may be arranged in a delta array. In this case, one pixel 101 may include the three sub-pixels 100R, 100G, and 100B that are arranged in a delta array.

For example, as illustrated in FIG. 20B, four sub-pixels 100R, 100G, 100B, and 100B each having a square shape in plan view may be arranged in a square array. In this case, one pixel 101 may include the four sub-pixels 100R, 100G, 100B, and 100B that are arranged in a delta array. The sub-pixels 100B and 100B may be arranged on a diagonal line of the square array. The sub-pixels 100B and 100B arranged on a diagonal line may be electrically connected to each other as illustrated in FIG. 21A. More specifically, for example, their respective first electrodes 21 of the sub-pixels 100B and 100B arranged on a diagonal line may be electrically connected to each other, or their respective first electrodes 21 and second electrodes 23 of the sub-pixels 100B and 100B arranged on a diagonal line may be electrically connected to each other.

For example, as illustrated in FIG. 21B, three sub-pixels 100R, 100G, and 100B each having a rectangular shape in plan view may be arranged in a stripe array. In this case, one pixel 101 may include the three sub-pixels 100R, 100G, and 100B arranged in the horizontal direction of the display surface. The sub-pixels 100R, 100G, and 100B each having a rectangular shape may be arranged such that their respective long sides are parallel to the vertical direction of the display surface. A plurality of the sub-pixels 100R of the same color may form a column extending in the vertical direction of the display surface, a plurality of the sub-pixels 100G of the same color may form a column extending in the vertical direction of the display surface, and a plurality of the sub-pixels 100B of the same color may form a column extending in the vertical direction of the display surface.

### Ninth Modification

The display device 10 according to the first embodiment may further include a color filter on the protective layer 15 or above the protective layer 15. The color filter includes, for example, a red filter portion, a green filter portion, and a blue filter portion. The color filter may further include a light shielding portion between the color filter portions. The red filter portion is provided above the light emitting element 20R, the green filter portion is provided above the light emitting element 20G, and the blue filter portion is provided above the light emitting element 20B. As described above, since the display device 10A includes the color filter, it is possible to increase the color purity of the display device 10.

The display device 10A according to the second embodiment and the display device 10B according to the third embodiment may further include the color filter.

### Tenth Modification

In the first to third embodiments, the example where their respective second electrodes 23 of the plurality of light emitting elements 20 included in the display region 110a are connected to one common electrode 24 has been described, but how the light emitting elements 20 included in the display region 110a and the common electrode 24 are connected to each other is not limited to such a connection form.

For example, the display device 10 may include a plurality of the common electrodes 24 in the display region 110a, and the plurality of light emitting elements 20 included in the display region 110a may constitute a plurality of groups. Each group may include two or more light emitting elements 20 adjacent to each other. The plurality of common electrodes 24 is arranged in an in-plane direction. Their respective second electrodes 23 of the two or more light emitting elements 20 constituting one group may be connected to one common electrode 24. In the present specification, the in-plane direction means a direction parallel to the first surface of the substrate 11A.

### Eleventh Modification

In the display device 10 according to the first embodiment, the sub-pixels 100R, 100G, and 100B may have first, second, and third resonator structures, respectively. The first resonator structure can resonate and emphasize red light contained in light emitted by the OLED layer 22R. The second resonator structure can resonate and emphasize green light contained in light emitted by the OLED layer 22G. The third resonator structure can resonate and emphasize blue light contained in light emitted by the OLED layer 22B.

### (First Example of Resonator Structure)

The first, second, and third resonator structures may each include the first electrode 21 and the second electrode 23. More specifically, for example, an optical path length between the first electrode 21 and the second electrode 23 in the red sub-pixel 100R may be set equal to a spectral peak wavelength of the red sub-pixel 100R. An optical path length between the first electrode 21 and the second electrode 23 in the green sub-pixel 100G may be set equal to a spectral peak wavelength of the green sub-pixel 100G. An optical path length between the first electrode 21 and the second electrode 23 in the blue sub-pixel 100B may be set equal to a spectral peak wavelength of the blue sub-pixel 100B.

The optical path length between the first electrode 21 and the second electrode 23 may be adjusted by making the first electrode 21 different in thickness among the light emitting elements 20R, 20G, and 20B and making the first surface of the first electrode 21 different in height among the light emitting elements 20R, 20G, and 20B.

### (Second Example of Resonator Structure)

The display device 10 may include a semi-transmissive reflective layer provided above the common electrode 24, and the resonator structure may include the first electrode 21 and the semi-transmissive reflective layer. More specifically, for example, an optical path length between the first electrode 21 and the semi-transmissive reflective layer in the red sub-pixel 100R may be set equal to the spectral peak wavelength of the red sub-pixel 100R. An optical path length between the first electrode 21 and the semi-transmissive reflective layer in the green sub-pixel 100G may be set equal to the spectral peak wavelength of the green sub-pixel 100G. An optical path length between the first electrode 21 and the semi-transmissive reflective layer in the blue sub-pixel 100B may be set equal to the spectral peak wavelength of the blue sub-pixel 100B.

The optical path length between the first electrode 21 and the semi-transmissive reflective layer may be adjusted by making a protective layer provided between the common electrode 24 and the semi-transmissive reflective layer different in thickness among the light emitting elements 20R, 20G, and 20B.

### (Third Example of Resonator Structure)

The display device 10 may include a reflective layer provided below the first electrode 21, and the resonator structure may include the reflective layer and the second electrode 23. More specifically, for example, an optical path length between the reflective layer and the second electrode 23 in the red sub-pixel 100R may be set equal to the spectral peak wavelength of the red sub-pixel 100R. An optical path length between the reflective layer and the second electrode 23 in the green sub-pixel 100G may be set equal to the spectral peak wavelength of the green sub-pixel 100G. An optical path length between the reflective layer and the second electrode 23 in the blue sub-pixel 100B may be set equal to the spectral peak wavelength of the blue sub-pixel 100B. In a case of the above-described configuration, a transparent electrode is used as the first electrode 21.

The optical path length between the reflective layer and the second electrode 23 may be adjusted by making an insulating layer provided as an optical path length adjustment layer between the reflective layer and the first electrode 21 different in thickness among the light emitting elements 20R, 20G, and 20B.

As described above, since the sub-pixels 100R, 100G, and 100B of the display device 10 include the first, second, and third resonator structures, respectively, it is possible to increase the color purity of the display device 10.

The sub-pixels 100R, 100G, and 100B of the display device 10A according to the second embodiment and of the display device 10B according to the third embodiment may include the above-described first, second, and third resonator structures, respectively.

### (Other Modifications)

Although the first to third embodiments of the present disclosure and modifications thereof have been specifically described above, the present disclosure is not limited to the above-described first to third embodiments and modifications thereof, and various modifications based on the technical idea of the present disclosure are possible.

For example, the configurations, methods, processes, shapes, materials, numerical values, and the like mentioned in the above-described first to third embodiments and modifications thereof are merely examples, and different configurations, methods, processes, shapes, materials, numerical values, and the like may be used as necessary.

For example, the configurations, methods, processes, shapes, materials, numerical values, and the like of the above-described first to third embodiments and modifications thereof can be combined with each other without departing from the gist of the present disclosure.

For example, the materials exemplified in the above-described first to third embodiments and modifications thereof can be used alone or in combination of two or more unless otherwise specified.

Furthermore, the present disclosure may also employ the following configurations.

(1)

A display device including:
a plurality of light emitting elements;
an insulating member; and
a common electrode, in which
the plurality of light emitting elements is two-dimensionally arranged,
the light emitting elements each include a first electrode, an organic layer including a light emitting layer, and a second electrode in this order,
the first electrode, the organic layer, and the second electrode are isolated for each of the light emitting elements,
the common electrode is provided on the second electrodes of two or more of the light emitting elements, and
the insulating member covers a lateral surface of the organic layer of each of the light emitting elements.
   (2)

The display device according to (1), in which
the insulating member includes a plurality of sidewalls, and
each of the sidewalls covers the lateral surface of the organic layer of a corresponding one of the light emitting elements.
   (3)

The display device according to (2), in which
a peripheral edge of the organic layer is located inside a peripheral edge of the first electrode, and
the common electrode covers the sidewalls.
   (4)

The display device according to (3), in which
an inner periphery of each of the sidewalls is located inside the peripheral edge of the first electrode, and
an outer periphery of each of the sidewalls is located outside the peripheral edge of the first electrode.
   (5)

The display device according to any one of (2) to (4), further including a first insulating layer, in which
the first insulating layer is provided between the sidewalls of the light emitting elements adjacent to each other, and
the common electrode is provided on the first insulating layer.
   (6)

The display device according to the above (5), in which an upper surface of the first insulating layer is almost the same in height as a top portion of each of the light emitting elements.

(7)

The display device according to (1), in which the insulating member includes a second insulating layer provided between the light emitting elements adjacent to each other.

(8)

The display device according to (7), in which an upper surface of the second insulating layer is almost the same in height as a top portion of each of the light emitting elements.

(9)

The display device according to (7) or (8), in which
the second insulating layer includes a plurality of layers, and
the plurality of layers is different from each other in at least one of refractive index or composition.
   (10)

The display device according to any one of (1) to (9), further including a light shielding layer, in which
the light shielding layer is provided on the common electrode, and
the light shielding layer has a plurality of openings, each of the openings being provided for a corresponding one of the light emitting elements.
   (11)

The display device according to (10), further including an auxiliary electrode, in which
the auxiliary electrode is provided at a peripheral edge of a region where the plurality of light emitting elements is provided,
the auxiliary electrode is connected to the common electrode, and
the light shielding layer covers the auxiliary electrode.
   (12)

The display device according to any one of (1) to (11), in which the common electrode is in contact with an entire upper surface of the second electrode.

(13)

An electronic device including the display device according to any one of (1) to (12).

### 5 Application Example

### (Electronic Device)

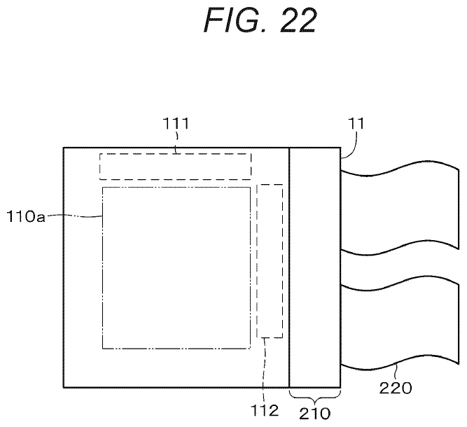

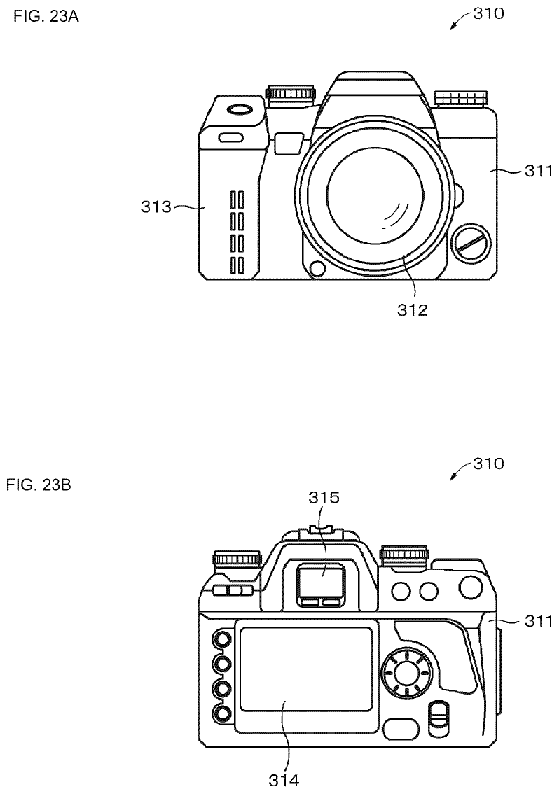

The display devices 10, 10A, and 10B (hereinafter referred to as “display device 10 and the like”) according to the above-described first to third embodiments and modifications thereof can be used for various electronic devices. The display device 10 and the like may be incorporated in various electronic devices, for example, as a module as illustrated in FIG. 22. Especially, this is suitable for an electronic view finder of a video camera or a single-lens reflex camera, a head mounted display or the like in which high resolution is required, used for enlarging near the eyes. This module may include a region 210 exposed without being covered with the protective layer 15 and the like on one short side of the circuit board 11, and external connection terminals (not illustrated) may be formed in this region 210 by extending wiring of the signal line drive circuit 111 and the scanning line drive circuit 112. A flexible printed circuit (FPC) 220 for inputting and outputting signals may be connected to the external connection terminals.

### First Specific Example

FIGS. 23A and 23B illustrate an example of an external appearance of a digital still camera 310. The digital still camera 310 is of a lens interchangeable single-lens reflex type, and includes an interchangeable imaging lens unit (interchangeable lens) 312 substantially at the center on a front surface of a camera main body (camera body) 311, and a grip 313 to be held by a photographer on a front left side.

A monitor 314 is provided at a position shifted to the left side from the center of a rear surface of the camera main body 311. An electronic view finder (eyepiece window) 315 is provided above the monitor 314. By looking through the electronic view finder 315, the photographer can visually confirm an optical image of a subject guided from the imaging lens unit 312 and determine a picture composition. The electronic view finder 315 includes any one of the display device 10 and the like.

### Second Specific Example

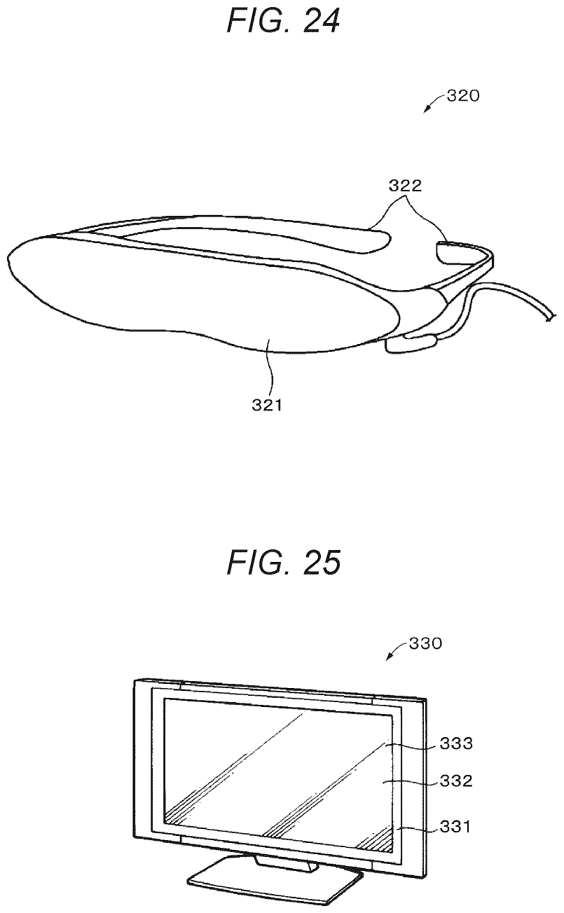

FIG. 24 illustrates an example of an external appearance of a head mounted display 320. The head mounted display 320 includes, for example, ear hooking portions 322 to be worn on the head of the user on both sides of a glass-shaped display unit 321. The display unit 321 includes any one of the display device 10 and the like.

### Third Specific Example

FIG. 25 illustrates an example of an external appearance of a television device 330. The television device 330 includes, for example, a video display screen unit 331 including a front panel 332 and a filter glass 333, and the video display screen unit 331 includes any one of the display device 10 and the like.

### REFERENCE SIGNS LIST

10, 10A, 10B Display device
11 Circuit board
11A Substrate
11B Insulating layer
12 Insulating layer
13 Sidewall
13a Insulating layer
14 Contact portion
14A Contact plug
15 Protective layer
16 Insulating layer
17 Insulating layer
18 Light shielding layer
18a Opening
19 Insulating layer
20 Light emitting element
21 First electrode
21A Contact plug
22R, 22G, 22B OLED layer
23 Second electrode
24 Common electrode
25 Inter-element insulating layer (first insulating layer)
26 Inter-element insulating layer (second insulating layer)
27 Inter-element insulating layer (first insulating layer)
31, 32, 33 Resist layer
100R, 100G, 100B Sub-pixel
110a Display region
110b Peripheral region
111 Signal line drive circuit
111a Signal line
112 Scanning line drive circuit
112a Scanning line
310 Digital still camera (electronic device)
320 Head mounted display (electronic device)
330 Television device (electronic device)

1. A display device comprising:
a plurality of light emitting elements;
an insulating member; and
a common electrode, wherein
the plurality of light emitting elements is two-dimensionally arranged,
the light emitting elements each include a first electrode, an organic layer including a light emitting layer, and a second electrode in this order,
the first electrode, the organic layer, and the second electrode are isolated for each of the light emitting elements,
the common electrode is provided on the second electrodes of two or more of the light emitting elements, and
the insulating member covers a lateral surface of the organic layer of each of the light emitting elements.

2. The display device according to claim 1, wherein
the insulating member includes a plurality of sidewalls, and
each of the sidewalls covers the lateral surface of the organic layer of a corresponding one of the light emitting elements.

3. The display device according to claim 2, wherein
a peripheral edge of the organic layer is located inside a peripheral edge of the first electrode, and
the common electrode covers the sidewalls.

4. The display device according to claim 3, wherein
an inner periphery of each of the sidewalls is located inside the peripheral edge of the first electrode, and
an outer periphery of each of the sidewalls is located outside the peripheral edge of the first electrode.

5. The display device according to claim 2, further comprising a first insulating layer, wherein
the first insulating layer is provided between the sidewalls of the light emitting elements adjacent to each other, and
the common electrode is provided on the first insulating layer.

6. The display device according to claim 5, wherein an upper surface of the first insulating layer is almost the same in height as a top portion of each of the light emitting elements.

7. The display device according to claim 1, wherein the insulating member includes a second insulating layer provided between the light emitting elements adjacent to each other.

8. The display device according to claim 7, wherein an upper surface of the second insulating layer is almost the same in height as a top portion of each of the light emitting elements.

9. The display device according to claim 7, wherein
the second insulating layer includes a plurality of layers, and
the plurality of layers is different from each other in at least one of refractive index or composition.

10. The display device according to claim 1, further comprising a light shielding layer, wherein
the light shielding layer is provided on the common electrode, and
the light shielding layer has a plurality of openings, each of the openings being provided for a corresponding one of the light emitting elements.

11. The display device according to claim 10, further comprising an auxiliary electrode, wherein
the auxiliary electrode is provided at a peripheral edge of a region where the plurality of light emitting elements is provided,
the auxiliary electrode is connected to the common electrode, and
the light shielding layer covers the auxiliary electrode.

12. The display device according to claim 1, wherein the common electrode is in contact with an entire upper surface of the second electrode.

13. An electronic device comprising the display device according to claim 1.
